(19) United States
(12) Patent Application Publication
(10) Pub. No.: US 2026/0333940 A1
(43) Pub. Date: Oct. 22, 2026

(54) BACK-CONTACT SOLAR CELL AND METHOD FOR PRODUCING A BACK-CONTACT SOLAR CELL

(71) Applicants: Erik HOFFMANN, Stuttgart (DE); Massimo CENTAZZO, Karlsruhe (DE)

(72) Inventors: Erik HOFFMANN, Stuttgart (DE); Massimo CENTAZZO, Karlsruhe (DE)

(73) Assignee: Silfab Solar Cells SC Inc., Fort Mill, SC (US)

(21) Appl. No.: 19/577,649

(22) Filed: Mar. 25, 2026

(30) Foreign Application Priority Data
Apr. 17, 2025 (DE) 1020251152993

(51) Int. Cl. H10F 77/20; H10F 10/14

(52) U.S. Cl. CPC H10F 77/219; H10F 10/14

(57) ABSTRACT

A back-contact solar cell and a method for manufacturing a back-contact solar cell are disclosed. The back-contact solar cell includes a semiconductor substrate with a front side and a rear side. The rear side includes first regions, second regions, and third regions. The first regions include a first tunnel layer, a first conductive layer, and a second conductive layer. The first conductive layer is etch-resistant or has a lower etch rate than the semiconductor substrate. The second conductive layer includes amorphous, microcrystalline, or polycrystalline silicon. The second regions include a second tunnel layer and the second conductive layer. The third regions include under-etched areas of the first regions. The solar cell further includes first electrodes in the first regions and second electrodes in the second regions. The first and second electrodes contact the second conductive layer. The first regions are each on a pedestal-like elevation.

### CROSS-REFERENCE TO RELATED APPLICATIONS

This application claims priority to German Pat. Appl. No. 10 2025 115 299.3, filed on Apr. 17, 2025, the contents of which are incorporated by reference herein in its entirety.

### FIELD OF THE INVENTION

The invention relates to a back-contact solar cell with features as described herein and a method for manufacturing a back-contact solar cell with such features.

### DISCUSSION OF THE BACKGROUND

In a back-contact solar cell, electrodes of opposite polarities, as well as emitter regions and base regions, are arranged on the back side of the solar cell. The back side of the solar cell is the side facing away from the sun during the operation of the solar cell. Accordingly, the front side of the solar cell is the side facing the sun.

Back-contact solar cells can generally achieve a higher efficiency than solar cells in which electrodes of one polarity are on the front side and electrodes of the opposite polarity are on the back side. In back-contact solar cells, the front side is not shaded by electrodes. To minimize resistance and recombination losses in back-contact solar cells, the electrodes of both polarities, as well as the emitter and base regions, are arranged alternately on the back side, with a small gap between the different regions.

Back-contact solar cells can generally achieve a higher efficiency than solar cells where electrodes of one polarity are on the front side and electrodes of the opposite polarity are on the back side. In back-contact solar cells, the front side is not shaded by electrodes. To minimize resistance and recombination losses in back-contact solar cells, the electrodes of both polarities, and thus also the emitter and base regions, are alternately arranged on the back with a small spacing between adjacent emitter and base regions.

Generating a large number of p-n junctions with small spacing is technically significantly more challenging than, for example, a conventional front- and rear-contact solar cell with a large-area, bilateral contact p-n junction. The alternately arranged emitter and base regions on the back side can be realized, for instance, using laser irradiation. In this process, n-type and p-type dopants are locally introduced into a semiconductor substrate by temporally and spatially separated melting of the surface with laser irradiation, thereby creating either a p-type or n-type doped region depending on the dopant. Such a laser doping method is disclosed, for example, in DE 10 2013 219 564 A1. The described structuring of the back side allows for efficiencies of over 20% due to low internal series resistances and high current yields.

Even higher efficiencies are essentially limited by recombination mechanisms in the base as well as on the heavily-doped contact and non-contact surfaces. Recombination in the base depends on the quality of the semiconductor substrate, and can only be influenced to a limited extent in the manufacturing process of the solar cell. Recombination mechanisms at the doped n-type and p-type surfaces are limited in the non-contact areas by Auger recombination only when there is good surface passivation, with Auger recombination increasing with the dopant concentration in silicon. In contact areas, where metal electrodes contact silicon, the contact with the metal leads to high interface recombination. During the manufacturing process, Auger recombination at the non-contact surfaces can be reduced by minimizing doping. A high dopant concentration is advantageous at the contact surfaces, as this reduces contact resistance and interface recombination.

To address this discrepancy, the use of so-called passivating or charge carrier-selective contacts is known, as seen in, for example, DE 10 2013 219 564 A1 or WO 2014/100004 A1. The electrodes do not directly contact the crystalline silicon wafer, which serves as an absorber, but are separated by a thin dielectric layer, such as a silicon oxide layer. The silicon oxide layer passivates the silicon surface, on the one hand. On the other hand, the silicon oxide layer is so thin that charge carriers (particularly electrons) can tunnel through the silicon oxide layer from the semiconductor to the electrode, or from the electrode to the semiconductor (depending on the polarity). Therefore, the silicon oxide layer can be referred to as a tunneling layer through which charge carriers can tunnel. The tunneling layer may also have small holes, e.g., in the nanometer (nm) range, that can allow for current flow.

In order to encourage the charge carriers to tunnel, an electric field can be present across the tunnel layer. The electric field can be generated, for example, by highly doped n-type or p-type silicon on the tunnel layer. The doping of this highly doped silicon layer above the tunnel layer leads to band bending in the silicon base below the tunnel layer. This means that conventional doping of the silicon base to create a p-n junction is no longer necessary. Since the silicon base is no longer, or at least only slightly, doped, Auger recombination in the base decreases. Due to the spatial separation of the metal/silicon interface of the electrodes from the silicon base, interface recombination also decreases. Nevertheless, a low contact resistance can be achieved because the electrodes make contact with the highly doped silicon layer. Doped silicon layers can be, for example, amorphous, polycrystalline, or microcrystalline silicon layers with a thickness of 20 nm to 400 nm, which can be deposited, for instance, by PECVD, LPCVD, APCVD, or PVD.

Back-contact solar cells with charge carrier-selective contacts of opposite polarities have so far achieved an efficiency of over 20%. However, the production of such solar cells is very complicated, as the two differently-doped passivating contacts have been made only using various complex masking and fabrication steps. High precision and fine resolution of the masking and fabrication have been necessary. The distance between the charge carrier-selective contacts of opposite polarities should not exceed the diffusion length of the free charge carriers. However, large distances can also lead to an increase in internal series resistance due to lateral current flow in the base.

The differently-doped silicon layers of the charge carrier-selective contacts can also be separated either by an undoped silicon layer or by a spatial separation (e.g., a trench or a break). Without such separation, the transition between the differently-doped layers has a defect-rich p-n junction, which limits the efficiency of the solar cell. Ideally, the separation should be as fine as possible, as a large area for separation can adversely affect the short-circuit current and the open-circuit voltage.

This “Discussion of the Background” section is provided for background information only. The statements in this “Discussion of the Background” are not an admission that the subject matter disclosed in this “Discussion of the Background” section constitutes prior art to the present disclosure, and no part of this “Discussion of the Background” section may be used as an admission that any part of this application, including this “Discussion of the Background” section, constitutes prior art to the present disclosure.

### SUMMARY OF THE INVENTION

It is therefore an object of the present invention to provide a rear contact solar cell and a method for manufacturing a rear contact solar cell, whereby the solar cell has a high efficiency and can be produced cost-effectively and efficiently.

These objects are met by a back-contact solar cell with features as described herein. The back-contact solar cell comprises a semiconductor substrate with a front side and a back side. The front side of the semiconductor substrate can form a front of the solar cell. The back side of the semiconductor substrate can form a back of the solar cell. The semiconductor substrate can include or be made of silicon. The semiconductor substrate can be or comprise a silicon wafer.

The back side of the semiconductor substrate (or the solar cell) comprises a plurality of first regions, a plurality of second regions, and a plurality of third regions.

The first regions include a layer stack comprising a first tunnel layer, a first conductive layer, optionally a second tunnel layer, and a second conductive layer. The first conductive layer is etch-resistant or has a lower etch rate than silicon (e.g., single crystal silicon). In particular, the first conductive layer can be resistant to (e.g., etch-resistant relative to) an alkaline or acidic etch. The second conductive layer (and/or the first conductive layer) can include or consist essentially of amorphous, polycrystalline, or microcrystalline silicon. The first tunnel layer may be on the semiconductor substrate in the first regions, with the remaining layers of the layer stack in the first regions in the aforementioned order. In particular, the layer stack in the first regions does not include a separate etch-barrier layer (e.g., separate from the first conductive layer).

The second regions include a stack of layers comprising a second tunnel layer and the second conductive layer. In the second regions, the second tunnel layer can be on the semiconductor substrate, or the second conductive layer can be on the second tunnel layer. The first regions and the second regions may each be or comprise passivating contacts. The third regions can, in particular, be free of the first conductive layer and/or free of the second conductive layer.

The third regions are or comprise under-etched areas of the first regions, in particular of the first conductive layer.

The solar cell comprises a plurality of first electrodes and a plurality of second electrodes. Each first electrode is in the first region and contacts the second conductive layer. Each second electrode is in the second region and contacts the second conductive layer. The first electrodes and/or the second electrodes can, in particular, at least partially penetrate the respective second conductive layer. The first electrodes can, in particular, penetrate the second conductive layer (e.g., completely) in the first regions and contact the first conductive layer.

Each of the first regions is on a pedestal-like elevation. The pedestal-like elevations may consist of or comprise the etched semiconductor substrate (or a part thereof), the first tunnel layer, the first conductive layer, the second tunnel layer, a first intermediate layer (see below), a second intermediate layer (see below), the second conductive layer and/or a passivation layer (e.g., a dielectric layer or stack of dielectric layers, see below), provided that these layers are present in the respective embodiment.

The elevations can each have a cross-section that expands (e.g., increases) at least partially, preferably completely, in a first direction. The elevations can each have a cross-section that tapers at least partially, preferably completely, in the first direction. The elevations can each have a cross-section that remains at least partially, preferably completely, constant or uniform in the first direction. In particular, the shape of the cross-section of the pedestal-like elevations can be trapezoidal or rectangular. The pedestal-like elevations can take any desired shape, particularly when the pedestal-like elevations encompass the semiconductor substrate and the first conductive layer. The elevations can extend from the backside of the solar cell in the first direction.

The first direction may refer to a direction pointing away from (e.g., orthogonal to) the back or backside surface of the semiconductor substrate or the solar cell. It is also conceivable that the first direction may be a direction pointing toward (e.g., orthogonal to) the back or backside surface of the semiconductor substrate or the solar cell. The first direction is particularly oriented perpendicular to the front and back of the semiconductor substrate or the solar cell. The first direction can extend outside of the solar cell.

This allows the third regions to be or comprise a recessed area that widens transversely to the first direction, and thus be substantially in the “shadow” (with respect to the first direction) of the first regions (particularly the first conductive layers). The first conductive layers (and second layers) in the first regions and the second conductive layers in the second regions, particularly the first and second regions, are therefore each separated from one another by the third regions. The third regions may form a step in the “shadow” of the first regions, especially the first conductive layer. In this way, separate differently doped charge-carrier-selective contacts with a fine separation of a few micrometers and high resolution can be implemented without further complex structuring steps. This separation can prevent a p-n junction from forming between the first conductive layers in the first regions and the second conductive layers in the second regions, which could limit the fill factor and thus the efficiency. Therefore, a solar cell with the highest possible efficiency can be realized, which is cost-effective and efficient to manufacture.

The second regions can be designed without under-etching. In other words, the second regions may specifically not be or include under-etched areas.

In particular, due to the etch-resistant first conductive layer, an etch barrier layer and its formation can be omitted. The structure and manufacturing of the solar cell can thus be further optimized.

The first conductive layers can comprise a p (positive)-type or n (negative)-type layer. The second conductive layers can comprise a p-type or n-type layer.

The third regions can have a width (or extend perpendicularly to the first direction) in a range of 0.1 μm to 20 μm (micrometers), in particular in a range of 1 μm to 10 μm.

The first tunnel layers can be or comprise passivation layers. The first tunnel layers can have a passivating effect. The first tunnel layers can serve for passivation.

The second tunnel layers can be or comprise passivation layers. The second tunnel layers can have a passivating effect. The second tunnel layers can serve for passivation.

The first and/or second tunnel layers can each be or comprise a dielectric layer, such as a silicon oxide (SiOx, which may be doped or undoped) or a silicon oxynitride (SiON), and/or an intrinsic layer, such as amorphous silicon, for example.

According to an advancement of the solar cell, the first conductive layers can include silicon carbide (SiC) or be made of silicon carbide.

This allows the first layers, which are conductive and etch-resistant, to be implemented simply.

According to an advancement of the solar cell, the first conductive layers can include carbon-doped silicon (Si:C) or be made of carbon-doped silicon.

This allows the first layers, which are conductive and etch-resistant, to be implemented simply.

The first conductive layers can include additional elements, e.g., phosphorus, nitrogen, boron, aluminum and/or gallium, to increase conductivity.

According to an embodiment of the solar cell, a first intermediate layer may be between the first conductive layer and the second conductive layer or, more specifically, the first conductive layer and the second tunnel layer in the first regions.

The first intermediate layer can be or comprise a diffusion barrier against dopants or contaminants, and/or can increase etching stability.

According to an embodiment of the solar cell, the first intermediate layers may each comprise a silicon oxide (e.g., silicon dioxide) or a silicon carbide with a higher carbon content compared to the first conductive layer. The first intermediate layers can be or comprise an almost pure carbon layer.

This allows the first intermediate layers to be implemented simply.

According to an embodiment of the solar cell, a second intermediate layer can be in the first regions between the first conductive layer and the first tunnel layer.

This can further optimize the passivation.

According to an embodiment of the solar cell, the second intermediate layers can each include doped polycrystalline material, in particular doped polycrystalline silicon, or be made of doped polycrystalline material, in particular doped polycrystalline silicon.

This allows the second intermediate layers to be implemented simply.

According to an embodiment of the solar cell, the third regions can each be undoped.

In this context, “undoped” refers to a lack of additional (process-related) doping, meaning the additional introduction of significant amounts of dopant(s). An undoped layer thus has the same or lower doping concentration as the semiconductor substrate. The semiconductor substrate may have a low doping concentration, for example in the range of 5×10¹⁶ cm⁻³. An “undoped” layer can therefore have the same low doping concentration. Accordingly, doping refers to doping that is additional compared to the semiconductor substrate. When an intrinsic amorphous silicon layer is used as a passivation layer in the form of a tunnel layer, it can differ from the semiconductor substrate, particularly from the “undoped” silicon.

This allows the third regions to be implemented simply. In particular, this makes it possible to achieve a clear (undoped) separation between the first regions and the second regions. According to one embodiment, the third regions can each have a third conductive layer. The surface of the semiconductor substrate in the area of the third regions can thus be doped. This can further improve the efficiency of the solar cell. According to one embodiment of the solar cell, a fourth conductive layer can be on the front side of the semiconductor substrate or the solar cell. The fourth conductive layer can be a deposited layer, that is, a layer formed or generated by deposition (e.g., blanket deposition). It is also conceivable that the fourth conductive layer is not a deposited layer, but is created by doping the semiconductor substrate or its (front) surface.

This can further improve the efficiency of the solar cell. The semiconductor substrate, the first conductive layers, the second conductive layers, the third conductive layers, the fourth conductive layer, and/or the third regions may have a doping according to one of the combinations listed in Table 1 below:

TABLE 1

| | | | | Front side or |
|---|---|---|---|---|
| | First | Second | Third conductive | fourth |
| Semiconductor | conductive | conductive | layer or third | conductive |
| substrate | layer | layer | region | layer |
| n | N | p | — | p |
| n | N | p | — | n |
| n | N | p | p | p |
| n | N | p | n | n |
| n | P | n | — | p |
| n | P | n | — | n |
| n | P | n | p | p |
| n | P | n | n | n |
| p | N | p | — | p |
| p | N | p | — | n |
| p | N | p | p | p |
| p | N | p | n | n |
| p | P | n | — | p |
| p | P | n | — | n |
| p | P | n | p | p |
| p | P | n | n | n |
| p | N | p | — | — |
| p | N | p | — | — |
| p | N | p | p | — |
| p | N | p | n | — |
| p | P | n | — | — |
| p | P | n | — | — |
| p | P | n | p | — |
| p | P | n | n | — |
| n | N | p | — | — |
| n | N | p | — | — |
| n | N | p | p | — |
| n | N | p | n | — |
| n | P | n | — | — |
| n | P | n | — | — |
| n | P | n | p | — |
| n | P | n | n | — |

Here, and in particular in Table 1, “p” refers to an additional positive doping compared to the semiconductor substrate, “n” refers to an additional negative doping compared to the semiconductor substrate, and “-” means no additional doping compared to the semiconductor substrate. Capitalization (i.e., “P” or “N”) may, but does not necessarily, refer to a heavier doping level or dose than lower case letters (i.e., “p” or “n”).

This allows the solar cell to be designed and implemented as flexibly as possible.

According to an advancement of the solar cell, the first conductive layers, the second conductive layers, the first intermediate layers, the second intermediate layers, the first tunnel layers and/or the second tunnel layers can each be free of breaks or openings. The first and/or the second tunnel layers can each be or comprise continuous layers. In particular, the first tunnel layers and/or the second tunnel layers are not penetrated by the first electrodes and/or the second electrodes.

This can further improve the efficiency of the solar cell.

The first conductive layers, the second conductive layers, the first intermediate layers and/or the second intermediate layers can each be or comprise an amorphous, semi-crystalline, or polycrystalline material. The first conductive layers, the second conductive layers, the first intermediate layers and/or the second intermediate layers can thus differ from the semiconductor substrate, which can be crystalline, in particular monocrystalline. The third conductive layers, in particular, may not be or comprise an amorphous, semi-crystalline, or polycrystalline material. In particular, the third conductive layers can be free of amorphous, semi-crystalline, or polycrystalline silicon.

According to a further development of the solar cell, a dielectric layer or a dielectric layer stack can be on the front of the semiconductor substrate or the solar cell as the outermost layer.

This allows for a passivation of the front side to be implemented simply.

According to an advancement of the solar cell, a dielectric layer or a dielectric layer stack can be on the back side of the semiconductor substrate or of the solar cell as the outermost layer. The dielectric layer or dielectric layer stack can each include a first discontinuity in the area of the first regions and a second discontinuity in the area of the second regions. Each first electrode can contact a second conductive layer through a first discontinuity. It is also conceivable that each first electrode can contact a first conductive layer through a first discontinuity and through a discontinuity in second conductive layer and second tunneling layer. Each second electrode can contact a second conductive layer through a second discontinuity.

This allows passivation and contacting of the backside to be implemented simply.

According to a further development of the solar cell, the third regions can each have a second tunnel layer and/or a dielectric layer or a dielectric layer stack (i.e., a passivation layer) as the outermost layer.

This makes it possible, in particular, to further optimize passivation in the third regions.

The above object(s) may also be met by a method for producing a back-contact solar cell according to the above explanations with features as described herein. The method includes the following steps:

Providing a semiconductor substrate with a front side and a backside.

Forming a first tunnel layer on the backside of the semiconductor substrate.

Forming a first conductive layer, particularly on the first tunnel layer, wherein the first conductive layer is etch-resistant or has a lower etch rate than silicon (e.g., monocrystalline silicon). The first conductive layer has interruptions in a plurality of etch areas, or in other words, the method may further comprise removing the first conductive layer in a plurality of etch areas after the formation of the first conductive layer. The first conductive layer can, for example, be deposited using a CVD process (chemical vapor deposition) or a PVD process (physical vapor deposition). The first conductive layer in the etch areas can be removed, for instance, by laser ablation or etching.

Etching in the etching areas, whereby the first conductive layer is at least partially undercut by the etching, creates the pedestal-like elevations and the plurality of third regions. The third regions are particularly underetched areas. The etching can comprise either wet chemical etching or dry etching.

Forming a second tunnel layer, particularly in the areas between the pedestal-like elevations.

Forming a second conductive layer by directional deposition, particularly in the areas between the pedestal-like elevations, especially in the etched areas, whereby due to the under-etching below the first conductive layer and the directional deposition of the second conductive layer, no second conductive layer is formed in the third regions. The third regions can be formed particularly in the “shadow” (with respect to the first direction) of the first conductive layer. The third regions can be shadowed by the first conductive layer, so that no formation or deposition of the second conductive layer can occur there.

With regard to the advantages achievable with the method, reference is made to the corresponding statements concerning the solar cell. Further development of the method can be accomplished using the measures described in connection with the solar cell and/or those explained further below.

According to an embodiment of the method, the method may further include the step(s) of:
forming a third conductive layer in the third regions and/or a fourth conductive layer on the front side (e.g., by furnace diffusion of a dopant, which may be diffused from a silicate glass layer containing a dopant, deposited in the third regions and/or on the front side).

According to an embodiment of the method, the method may further include the step of:
removing the silicate glass layer (for example, a phosphosilicate glass layer or a borosilicate glass layer) formed during the furnace diffusion, in particular by (wet chemical) etching.

According to an embodiment of the method, the method may further include the step of:
forming a dielectric layer or a dielectric layer stack on the front side and/or the back side.

According to an embodiment of the method, the method may further include the step of:
forming first electrodes and/or second electrodes.

The method particularly includes anisotropic or isotropic etching of the first tunnel layer and/or the semiconductor substrate. The etching can be performed after depositing or growing the first tunnel layer, the second intermediate layer and/or the first conductive layer and, if necessary, removal of the etch resistant layer in the etch areas. The etching can remove, for example, approximately 0.3 μm to 20 μm (an etch depth), in particular 1 μm to 10 μm of silicon along the first direction (i.e., perpendicular to the substrate surface). In doing so, regardless of whether the etching is performed anisotropically or isotropically, under-etching of or below the first conductive etch-resistant layer particularly occurs.

After the growth or deposition of the second tunnel layer, which passivates the surface of the semiconductor substrate exposed by etching, the second conductive layer can be deposited, particularly using a directional process, such as physical vapor deposition (PVD). Unlike common chemical vapor deposition processes (PECVD, LPCVD, APCVD), little or no material (e.g., few or no particles) is/are deposited perpendicular to the first direction (i.e., on surfaces perpendicular to the deposition direction of the material/particles). In particular, this prevents material/particles, or at least reduces the material/number of particles, from being deposited beneath or in the undercut areas of or below the first conductive layer (that is, in or directly under the shadowed regions). This allows the formation of the third regions, which in particular do not include the first or the second conductive layer. A p-n junction therefore cannot form between the first conductive and second conductive layers, but only between a conductive layer and the semiconductor substrate (silicon wafer). This allows a high fill factor and a high efficiency to be achieved.

In other words, especially during etching in the etched areas, isotropic or anisotropic undercutting of or below the first conductive layer occurs. The deposition of the second conductive layer can be carried out using a physical, directional (e.g., unidirectional) gas-phase and/or plasma-based deposition. As a result, the second conductive layer does not deposit on all exposed surfaces on the back of the semiconductor substrate or the solar cell, but is at least interrupted in the shadowed areas of the undercut. Therefore, no additional process step is required to separate the first conductive layer in the first regions and the second conductive layer in the second regions. Furthermore, this separation (i.e., areas without the first and second conductive layers) extends over a width of up to a few micrometers (approximately the sum of the etch depth and the undercut width). This allows for an ultrafine separation of charge carrier-selective contacts, in the micrometer or sub-micrometer range.

According to a further development of the method, the process can further include the step:

Forming a first intermediate layer in the first regions, after forming the first conductive layer. The formation of the first intermediate layer can be carried out before forming the second conductive layer. The first conductive layer and the first intermediate layer can be deposited using a CVD or PVD process. The first conductive layer and the first intermediate layer can be formed or deposited in a single process step, with the CVD process step for forming or depositing the first intermediate layer being adjusted, for example, by modifying one or more gas flows or plasmas (e.g., to include an additional component or remove an existing component), or in a PVD process, by adjusting the target and/or deposition conditions.

The first intermediate layer can be formed after the first conductive layer is formed. The first intermediate layer can be removed in the etched areas, for example, by ablation, such as laser ablation. The first intermediate layer can also be structured with etched areas, for example, using a mask.

The first intermediate layer can be made of or comprise silicon carbide or a silicon oxide, and the silicon carbide can have an increased carbon content (e.g., relative to stoichiometric SiC). The first intermediate layer is intended to reduce or prevent the diffusion of dopants between the first and second conductive layers. It can also reduce the diffusion of impurities that may be present in the second conductive layer into the first conductive layer and into the semiconductor substrate, which can be or comprise a silicon substrate. The first intermediate layer can have a high electrical resistance. However, the first intermediate layer may be sufficiently thin (less than 2 nm), so that its resistance does not significantly affect the efficiency of the solar cell.

According to a further development of the method, the process may further include the step of:

Forming a second intermediate layer in the first regions. The second intermediate layer can be formed before forming the first conductive layer. The second intermediate layer can be removed in the etch areas before etching the etch areas. The second intermediate layer can be removed by etching in the etch areas.

The second intermediate layer can prevent a reaction between the oxygen of the oxide-containing first tunnel layer and the carbon of the first conductive layer, which can be or comprise a SiC layer. At elevated temperatures (for example, for the crystallization of the second conductive layer or the firing of the electrodes), the carbon of the first conductive layer, which can be or comprise a SiC layer, can react with the oxygen of the first tunnel layer, thereby eliminating the passivating properties of the first tunnel layer. The second intermediate layer can, for example, comprise an initially intrinsic silicon layer. During the aforementioned high-temperature step, the carbon can thus be separated from the oxygen, and the first tunnel layer can be preserved. During the high-temperature step, dopant from the first conductive layer can also diffuse into the second intermediate layer, so that the second intermediate layer is subsequently doped and is no longer intrinsic.

Both intermediate layers can also be formed in the first regions. Thus, in the first regions, a first intermediate layer can be between the first and the second conductive layer, and more specifically, the first conductive layer and the second tunnel layer, and a second intermediate layer can be between the first tunnel layer and the first conductive layer.

### BRIEF DESCRIPTION OF THE DRAWINGS

Further features, details, and advantages of the invention appear from the wording of the claims as well as from the following description of embodiments with reference to the drawings, which show:

FIG. 1 shows a schematic cross-section of a back-contact solar cell according to a first embodiment;

FIG. 2 shows a schematic cross-section of the back-contact solar cell according to a second embodiment;

FIG. 3 shows a schematic cross-section of the back-contact solar cell according to a third embodiment; and

FIGS. 4 to 6 schematically show cross-sections of structures formed during a method for manufacturing a back-contact solar cell.

### REFERENCE NUMBERS IN THE DRAWINGS

10—Back-contact solar cell; 12—Semiconductor substrate; 14—Front side; 16—Back side; 18—First region; 20—Second region; 22—Third region; 24—First tunnel layer; 26—First conductive layer; 28—Second conductive layer; 30—Second tunnel layer; 32—First electrode; 34—Second electrode; 36—Pedestal-like elevation; 38—First intermediate layer; 40—Second intermediate layer; 42—Fourth conductive layer; 44—Dielectric layer or layer stack; 46—First interruption; 48—Second interruption; 50—Etching region; 52—First direction.

### DETAILED DESCRIPTION

Reference will now be made in detail to various embodiments of the invention, examples of which are illustrated in the accompanying drawings. While the invention will be described in conjunction with the following embodiments, it will be understood that the descriptions are not intended to limit the invention to these embodiments. On the contrary, the invention is intended to cover alternatives, modifications and equivalents that may be included within the spirit and scope of the invention as defined by the appended claims. Furthermore, in the following detailed description, numerous specific details are set forth in order to provide a thorough understanding of the present invention. However, it will be readily apparent to one skilled in the art that the present invention may be practiced without these specific details. In other instances, well-known methods, procedures, components, and circuits have not been described in detail so as not to unnecessarily obscure aspects of the present invention. Furthermore, it should be understood that the possible permutations and combinations described herein are not meant to limit the invention. Specifically, variations that are not inconsistent may be mixed and matched as desired.

The technical proposal(s) of embodiments of the present invention will be fully and clearly described in conjunction with the drawings in the following embodiments. It will be understood that the descriptions are not intended to limit the invention to these embodiments. Based on the described embodiments of the present invention, other embodiments can be obtained by one skilled in the art without creative contribution and are in the scope of legal protection given to the present invention.

Furthermore, all characteristics, measures or processes disclosed in this document, except characteristics and/or processes that are mutually exclusive, can be combined in any manner and in any combination possible. Any characteristic disclosed in the present specification, claims, Abstract and FIGURES can be replaced by other equivalent characteristics or characteristics with similar objectives, purposes and/or functions, unless specified otherwise.

In the following description and in the FIGURES, corresponding components and elements are assigned the same reference numerals. For the sake of clarity, not all reference numerals are shown in every figure.

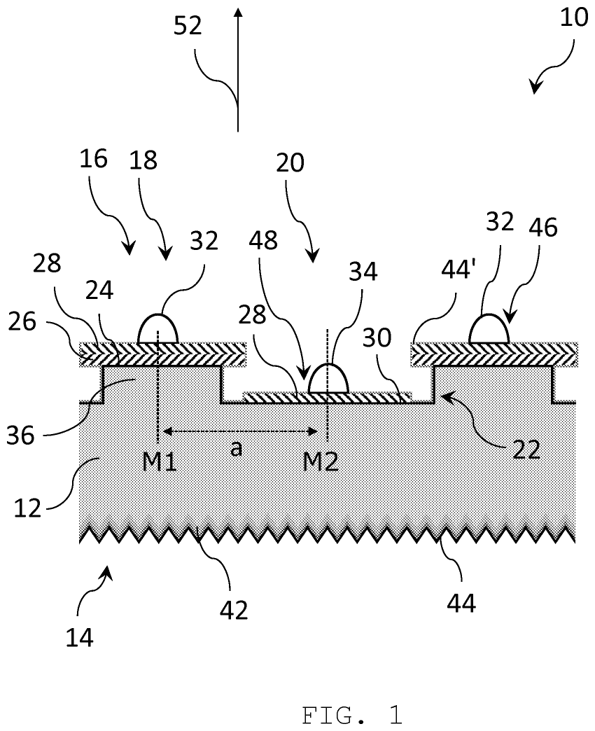

FIG. 1 shows a schematic cross-section of a back-contact solar cell 10 according to a first embodiment. In this example, the solar cell 10 includes a crystalline n-type semiconductor substrate 12. The semiconductor substrate 12 forms a silicon base and serves as an absorber (e.g., of light energy or radiation). In another embodiment, the semiconductor substrate 12 may also be a crystalline p-type silicon base.

The semiconductor substrate 12 comprises a front side 14 and a back side 16. The front side 14 can form a front side of the solar cell 10. The back side 16 can form a back side of the solar cell 10. In operation, the front side 14 of the solar cell 10 is oriented toward the sun. In the illustrated embodiment, the front side 14 is textured.

The back side 16 comprises a plurality of first regions 18, a plurality of second regions 20, and a plurality of third regions 22.

The first regions 18 include a layer stack that comprises a first tunnel layer 24, a first conductive layer 26, and a second conductive layer 28. The first conductive layer 26 is etch-resistant or has a lower etch rate than silicon (e.g., monocrystalline silicon). The first conductive layer 26 may have high etch selectivity relative to the semiconductor substrate 12. In other words, the semiconductor substrate 12 may be etched at a rate that is 5 times or greater than the etching rate of the first conductive layer 26 under the same conditions. The second conductive layer 28 may include or be made of amorphous, polycrystalline, or partially crystalline silicon. It is conceivable that a second tunnel layer 30 can be between the first conductive layer 26 and the second conductive layer 28 in the first regions 18 (not shown). In the present case, the first tunnel layer 24 is on the semiconductor substrate 12, the first conductive layer 26 is on the first tunnel layer 24, and the second conductive layer 28 is on the first conductive layer 26.

The second regions 20 each include a layer stack that comprises a second tunnel layer 30 and a second conductive layer 28. Here, the second tunnel layer 30 is on the semiconductor substrate 12, and the second conductive layer 28 is on the second tunnel layer 30.

Each of the first regions 18 and the second regions 20 may be or comprise a passivating contact. The third regions 22 are or comprise under-etched regions of the first regions 18, in particular of the first conductive layer 26.

The solar cell 10 comprises multiple first electrodes 32 and multiple second electrodes 34. Each first electrode 32 is in a first region 18 and contacts a second conductive layer 28. It is also conceivable that each first electrode can contact the (underlying) first conductive layer 26 through the second conductive layer 28. Each second electrode 34 is in a second region 20 and contacts a second conductive layer 28.

Each of the first regions 18 is on a pedestal-like elevation 36.

The first conductive layers 26 can include silicon carbide. The first conductive layers 26 can be formed from silicon carbide.

The first conductive layers 26 can each include carbon-doped silicon. The first conductive layers 26 can each be formed from carbon-doped silicon.

The first conductive layers 26 can include additional elements, such as phosphorus, nitrogen, boron, aluminum, and/or gallium, to increase the conductivity of the first conductive layer 26.

The third regions 22 can be undoped. The third regions 22 can have a third conductive layer therein. The third conductive layer can be or comprise a doped surface of the semiconductor substrate 12.

A fourth conductive layer 42 can be on the front side 14. The fourth conductive layer 42 can be or comprise a doped silicon layer, such as p-type doped silicon. The fourth conductive layer 42 can form a so-called “Front Floating Emitter” (FFE), an emitter with a p-n junction (i.e., with doping opposite to that of the semiconductor substrate 12). The fourth conductive layer 42 can be doped with a p-type dopant, for example boron, particularly with a dopant concentration of about 5×10¹⁷ cm⁻³ to 1×10²⁰ cm⁻³, preferably about 5×10¹⁸ cm⁻³ to 5×10¹⁹ cm⁻³.

In another embodiment, the fourth conductive layer 42 can include an n-type doping, especially with a comparable or identical dopant concentration as described in the previous paragraph. In this case, the doping on the front side 14 is referred to as a “Front Surface Field” (FSF), meaning a doping equivalent to the doping of the semiconductor substrate 12. The fourth conductive layer 42 can be doped with an n-type dopant, for example phosphorus, particularly with a dopant concentration of about 5×10¹⁷ cm⁻³ to 1×10²⁰ cm⁻³, preferably about 5×10¹⁸ cm⁻³ to 5×10¹⁹ cm⁻³.

The front side 14 may include a dielectric layer or a stack of dielectric layers 44 as the outermost layer. In other words, the front side 14 can be covered with the dielectric layer or the stack of dielectric layers 44.

The back side 16 may include a dielectric layer or a stack of dielectric layers 44′ as the outermost layer, wherein the dielectric layer or the stack of dielectric layers 44′ includes a first interruption 46 in each of the first regions 18 and a second interruption 48 in each of the second regions 20. Each first electrode 32 contacts the second conductive layer 28 through the first interruption 46. Each second electrode 34 contacts the second conductive layer 28 through the second interruption 48. It is also conceivable that in the first regions 18, the first electrode 32 penetrates the second conductive layer 28 and contacts the first conductive layer 26.

The first and/or second interruptions 46, 48 can, for example, be continuous or segmented interruptions, and may have a round, oval, square, rectangular, linear or pill shape (e.g., in a layout or top-down view). Thus, correspondingly shaped contact surfaces can be provided for the first and second electrodes 32, 34 (for example, point- or circular-shaped contact surfaces, or linear or segmented contact surfaces).

The dielectric layers or the dielectric layer stacks 44, 44′ can passivate the front side 14 and/or the back side 16, reduce reflections on the front side 14, and improve the light absorption of the solar cell 10. The dielectric layers 44, 44′ may comprise, for example, an aluminum oxide (AlOx, such as Al₂O₃), a silicon oxide (SiOx, such as silicon dioxide), or a silicon nitride (SiNx, such as Si₃N₄). The dielectric layers 44, 44′ can be or comprise a layer stack (i.e., consisting of a plurality of layers). The layer stack can comprise or consist essentially of two or more layers, for example, AlOx, SiOx, and/or SiNx. Other layers for reducing reflection and/or improving passivation are also conceivable.

The dielectric layer or the dielectric layer stack 44 on the front side 14 and the dielectric layer or the dielectric layer stack 44′ on the back side 16 can be constructed identically or differently.

The dielectric layer 44 on the front side 14 may comprise two layers. The dielectric layer 44′ on the back side 16 may comprise a single layer. Alternatively, the dielectric layer 44 on the front side 14 may comprise a single layer, and the dielectric layer 44′ on the back side 16 may comprise two layers.

The third regions 22 can each include a second tunnel layer 30. Alternatively or additionally, the third regions 22 can each include the dielectric layer or dielectric layer stack 44′ (or parts thereof). The second tunneling 30 layer may be a continuous layer covering the first conductive layer 26 in the first region 18, the semiconductor substrate 12 surface in the second region 20 and the semiconductor substrate 12 surface in the third regions 22.

A surface of the back side 16 can, for example, be textured over the entire surface or chemically polished over the entire surface. The surface of the back side 16 can also include a combination of textured areas and polished areas. For example, the surface in the first regions 18 may be polished and in the second regions 20 may be textured (or vice versa). Chemical polishing can describe the surface, for instance, after an anisotropic silicon etch with hot potassium hydroxide.

The first regions 18 and the second regions 20 are each side by side and alternating with each other. A distance a between a center M1 of a first region 18, here of n-type doping, and a center M2 of the next first region 18, here of n-type doping, is, for example, between 100 μm and 3000 μm, or any distance or range of distances therein (e.g., preferably between 400 μm and 2000 μm). A distance between the center of a second region 20, here of p-type doping, and the center of the next second region 20, here of p-type doping, can, for example, also be between 100 μm and 3000 μm, or any distance or range of distances therein (e.g., preferably between 400 μm and 2000 μm).

Over the area of the back side 16, a ratio of the total area of the p-type doped regions to the total area of the n-type doped regions can range from 1:9 to 9:1, particularly from 2:8 to 8:2, preferably from 3:7 to 7:3.

The alternating pattern of the first and second regions 18, 20 can, in principle, extend completely or at least approximately completely over the entire back side 16 of the semiconductor substrate 12 or the solar cell 10. However, the alternating pattern may also be interrupted locally, e.g., in areas where current-collecting rails or bus bars are provided.

The thickness of the first conductive layers 26 and/or the second conductive layers 28 can, for example, be 10 nm to 400 nm. The first conductive layers 26 and the second conductive layers 28 can have the same layer thickness. It is also conceivable that the first conductive layers 26 and the second conductive layers 28 may have different layer thicknesses.

The first conductive layers 26 and/or the second conductive layers 28 can be doped with an n-type dopant (e.g., phosphorus or n-type nitrogen), or with a p-type dopant (e.g., boron or aluminum), at a concentration of, for example, 1×10¹⁹ cm 3 to 1×10²² cm⁻³, preferably from 5×10¹⁹ cm⁻³ to 2×10²¹ cm⁻³.

The first and/or second tunnel layers 24, 30 can each be or comprise a dielectric layer. For example, the first and/or second tunnel layers 24, 30 may comprise a layer of a silicon oxide (SiOx) or a layer of a silicon oxynitride (SiON). The first and/or second tunnel layers 24, 30 can passivate the surface of the semiconductor substrate 12. For example, the first and/or second tunnel layers 24, 30 may have a thickness of 0.5 nm to 4 nm. This, in particular, enables the tunneling of charge carriers.

The first and/or second tunnel layers 24, 30 can each be or comprise an intrinsic amorphous silicon layer. The amorphous silicon layer can be hydrogenated, that is, saturated with hydrogen. The first and/or second tunnel layers 24, 30 can passivate the surface of the semiconductor substrate 12. The first and/or second tunnel layers 24, 30 can, for example, have a thickness of 0.5 nm to 20 nm. This can enable the tunneling of charge carriers.

The first and/or second tunnel layers 24, 30 can each be free of breakthroughs or openings. It is also conceivable that the first and/or second tunnel layers 24, 30 may have openings (e.g., so-called pinholes) with a width or diameter in the nm range (e.g., 0.5-10 nm). This can create an ohmic contact between the semiconductor substrate 12 and the first conductive layer 26 or the second conductive layer 28.

The first conductive layers 26 and/or the second conductive layers 28 can also each be free of breakthroughs or openings.

The first regions 18 and the second regions 20 are, in the present invention, separated from each other by the third regions 22. The third regions 22 may each include the second tunnel layer 30 and a dielectric layer 44′. However, the second tunnel layer 30 in the third regions 22 typically serves a passivation function, rather than a tunneling function.

In the first embodiment depicted in FIG. 1, the semiconductor substrate 12 is undoped in the third regions 22. The dopant concentration of or in the third regions 22 therefore corresponds in particular to the dopant concentration of the semiconductor substrate 12. The surface of the third regions 22 can each be covered or be passivated with the dielectric layer or layer stack 44′. For this purpose, the dielectric layer (or dielectric layer stack) 44′, unlike the second conductive layer 28, can be without a specific orientation and can also cover the third regions 22. In fact, when conformally deposited, the dielectric layer or layer stack 44′ can provide a beneficial passivation in the third areas.

In FIG. 1, the pedestal-like elevations 36 each have a constant cross-sectional width (e.g., along a first direction 52) up to the first conductive layer 26. In other words, the elevations 36 here have a cross-section that is rectangular below the first conductive layer 26. The first conductive layer 26 and/or the second conductive layer 28 may represent the greatest extent of the respective elevation 36 across the first direction 52 in the first region 18. In other words, the first conductive layer 26 and/or the second conductive layer 28 may be the widest (with respect to the first direction 52) section of the respective elevation 36.

In the present disclosure, the first direction 52 is oriented away from the back side 16. The first direction 52 is oriented perpendicular to the surfaces of the back side 16 and the front side 14. In FIG. 1, the first direction 52 is oriented from bottom to top. The first direction 52, in particular, does not pass through the solar cell 10.

The cross-section of the pedestal-like projections 36 can have a concave or convex shape (e.g., along a sidewall) or have sloped or tapered sidewalls. The cross-section of the pedestal-like projections 36 may have rounded corners and/or irregularities, e.g., a texture, on its walls or flanks.

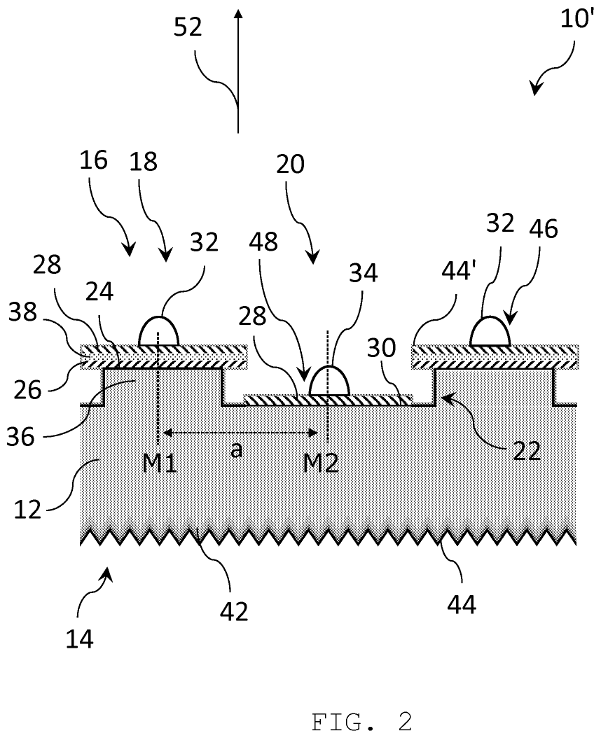

FIG. 2 shows a schematic cross-section of the back-contact solar cell 10′ according to a second embodiment. The second embodiment differs from the first embodiment shown in FIG. 1 as follows:

In the present disclosure, the first regions 18 may further include a first intermediate layer 38 between the first conductive layer 26 and the second conductive layer 28. The first intermediate layers 38 in the first regions 18 can be free of openings.

The first intermediate layers 38 can each comprise a silicon oxide (e.g., silicon dioxide, undoped or doped with carbon or boron and/or phosphorous). The first intermediate layers 38 can be made of a silicon oxide.

The first intermediate layers 38 can each comprise silicon carbide or silicon-rich silicon carbide, with a higher carbon content than the first conductive layer 26. This can increase etching stability and reduce the diffusion of elements (dopants, impurities) between the first and second conductive layers 26, 28.

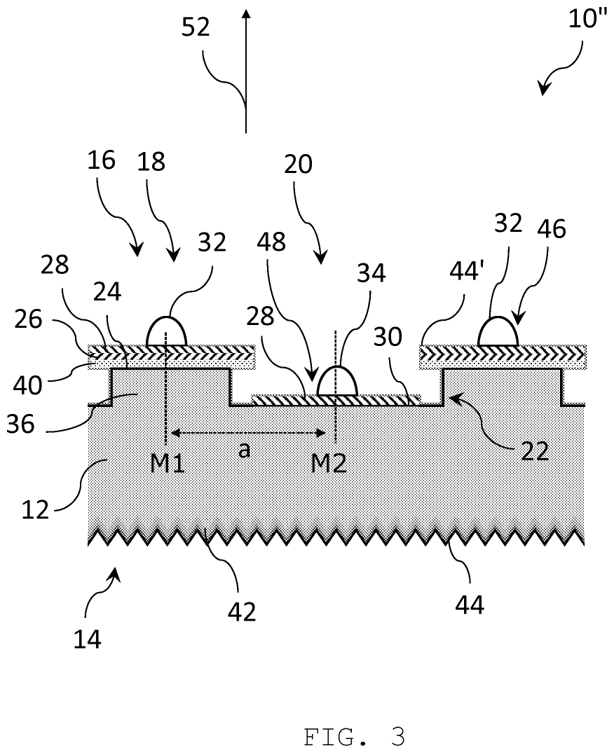

FIG. 3 shows a schematic cross-section of the back-contact solar cell 10″ according to a third embodiment. The third embodiment differs from the first embodiment shown in FIG. 1 as follows:

In the present disclosure, the first regions 18 may further include a second intermediate layer 40 between the first conductive layer 26 and the first tunnel layer 24. The second intermediate layers 40 in the first regions 18 can be without interruptions or openings.

The second intermediate layers 40 can each include a doped polycrystalline material, in particular a doped polycrystalline silicon. The second intermediate layers 40 can be or comprise a doped polycrystalline material, in particular a doped polycrystalline silicon. The doped polycrystalline silicon may be doped with one or more of boron, aluminum, phosphorous, and arsenic.

It is conceivable that in a further embodiment the first regions 18 each include both a first intermediate layer 38 and a second intermediate layer 40. The second embodiment shown in FIG. 2 can therefore be combined with the third embodiment shown in FIG. 3.

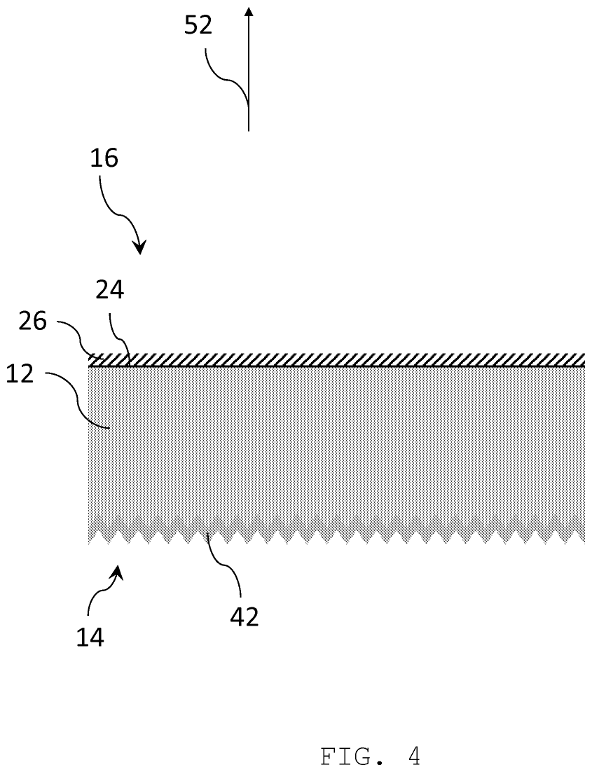

FIGS. 4 to 6 show a method for manufacturing a back-contact solar cell 10. Using the method described below, a solar cell 10 can be manufactured according to the above embodiments. The solar cell 10 may correspond to the solar cells 10-10″ shown in FIGS. 1 to 3.

First, a semiconductor substrate 12 with a front side 14 and a back side 16 is provided. The front side 14 of the semiconductor substrate 12 may correspond to a front side of the solar cell 10. Accordingly, the back side 16 of the semiconductor substrate 12 may correspond to a back side of the solar cell 10.

The semiconductor substrate 12 can be textured using an isotropic etch, particularly on the front side 14 and the rear side 16. An additional etching before texturing to remove sawing damage is possible. Other methods for texturing are also conceivable.

The semiconductor substrate 12 can undergo a full-area diffusion, for example a furnace diffusion, to dope the surfaces, particularly on the front side 14 and rear side 16. In this way, a fourth conductive layer 42 can be formed on the front side 14. It can be doped with either a p-type or an n-type dopant, for example boron or phosphorus. Depending on the doping, the dopant forms a so-called “Front Floating Emitter” or a “Front Surface Field” on the front side 14 of the semiconductor substrate 12.

During diffusion (for example, furnace diffusion), a dopant-rich silicate glass, such as a borosilicate glass (BSG) or a phosphosilicate glass (PSG), can grow or be deposited on one or both surfaces 14, 16 of the semiconductor substrate 12. This can lead to the formation of a silicate glass layer on either or both of the front side 14 and the back side 16 of the semiconductor substrate 12. On the back side 16 of the semiconductor substrate 12, the silicate glass layer is undesirable and should be completely or at least partially suppressed during diffusion, or removed in subsequent steps. This removal can be achieved by etching. In particular, for a solar cell 10 with a p-type semiconductor substrate 12, this diffusion step can also be skipped, so that the doping on the front side 14 of the semiconductor substrate 12 does not exceed the base doping of the semiconductor substrate 12. This can also apply to a solar cell 10 with an n-type semiconductor substrate 12.

A first tunnel layer 24 is formed on the backside 16 of the semiconductor substrate 12. This tunnel layer 24 can be grown (e.g., by thermal oxidation) or deposited (e.g., by PVD or CVD). The thickness of the first tunnel layer 24 can range between 5 and 200 angstroms. The first tunnel layer 24 can comprise or be made of a silicon oxide (e.g., SiO₂). Other dielectric substances or materials that can serve for surface passivation are also conceivable, provided they allow the passage of charge carriers. For example, the first tunnel layer 24 can be or comprise an a-Si:H layer. If necessary, the first tunnel layer 24 can also be grown or deposited on the front side 14. However, deposition on the front side 14 has little or no decisive influence on the subsequent process, and may need to be removed if necessary and is therefore not further considered.

A first conductive layer 26 is then formed. The first conductive layer 26 can be formed on the first tunnel layer 24. The first conductive layer 26 is etch-resistant or has at least a slower etch rate than the silicon wafer in a silicon etch. The first conductive layer 26 can be formed by deposition. The thickness of the first conductive layer 26 can be between 10 nm and 400 nm. The deposition of the first conductive layer 26 can, for example, be carried out by a CVD or PVD process.

The first conductive layer 26 serves as an etch barrier against an alkaline etch in a subsequent process step. The first conductive layer 26 can also fully or only partially cover the front side 14, for example, at the edges.

FIG. 4 shows the semiconductor substrate 12 with the first tunnel layer 24 and the first conductive layer 26 on the backside 16 of the semiconductor substrate 12, and a fourth conductive layer 42 on the front side 14 of the semiconductor substrate 12.

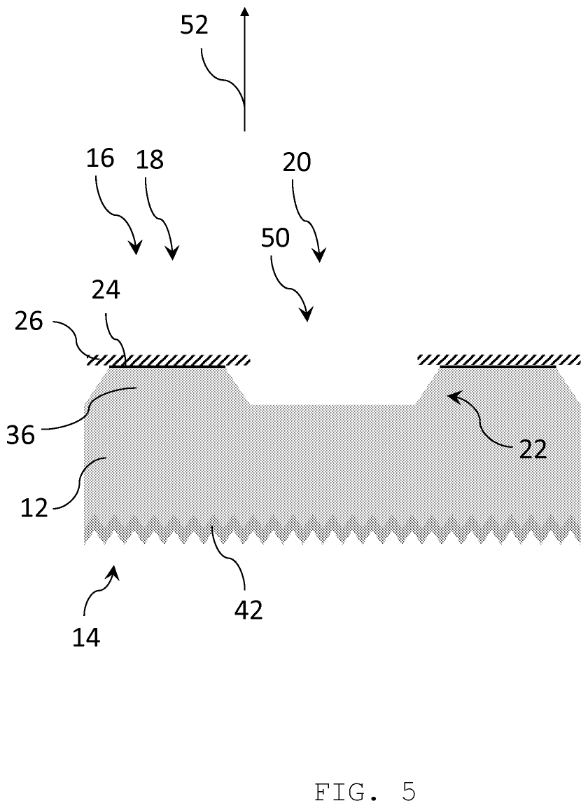

After forming the first conductive layer 26, it is removed in a plurality of etching areas 50 (see FIG. 5). This can be done, for example, by laser ablation, or wet chemical or dry (e.g., plasma-based) etching. The ablation or etching width can range between 50 μm and 2000 μm. The distance (center-to-center) between two etching areas 50 can range between 100 μm and 3000 μm or any distance or range of distances therein (e.g., 200-3000 μm). Laser ablation can be carried out in a linear fashion and result in a so-called “interdigitated” pattern. This pattern can be interrupted in areas of the solar cell 10 configured to contain current-collecting busbars. When removing the first conductive layer 26 in the etching areas 50, the first tunnel layer 24 can also be partially or completely removed. In addition, the semiconductor structure 12 can also be partially removed on its rear side 16.

Alternatively, the first conductive layer 26 can already be deposited with a structure/pattern, meaning with interruptions in the etching areas 50 on top of the first tunnel layer 24. This can be achieved, for example, by deposition through a mask or a printing process.

Subsequently, the exposed material(s) in the etching areas 50 are etched to produce the pedestal-like elevations 36 and third regions 22 (see FIG. 5). The first regions 18 can be on the elevations 36. Alternatively, the first regions 18 can form part of the elevations 36. The first regions can be defined by the elevations 36.

The second regions 20 are between the elevations 36. In this present disclosure, in particular, the first tunnel layer 24 and partially the semiconductor substrate 12 on the backside 16 are removed in the second regions 20 by etching. The etching can comprise wet chemical etching with an aqueous acidic or alkaline solution or by dry etching, either of which can, for example, remove the silicon isotropically or anisotropically. In this case, the first conductive layer 26 is under-etched, creating the third regions 22, which are particularly shadowed along the first (vertical) direction 52 by the first conductive layer 26. The first tunnel layer 24 can also be under-etched. The depth of the etched regions 50 is determined by the etch depth and can, for example, range between 0.3 μm and 20 μm.

Etching can be carried out in a single-sided process only on the backside 16.

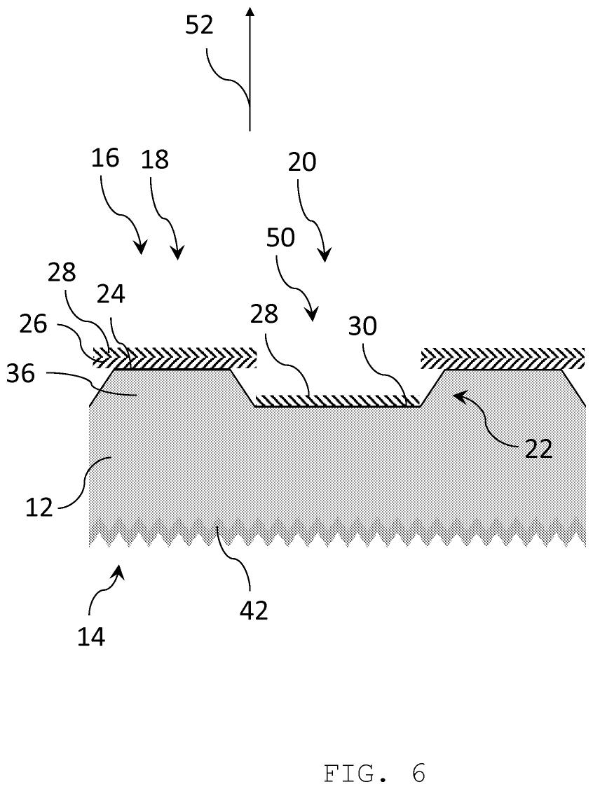

In the next step, the second tunnel layer 30 is formed (see FIG. 6). The second tunnel layer 30 can be formed between the pedestal-like elevations 36 and, if necessary or desired, on the first conductive layers 26. The second tunnel layer 30 can be formed by deposition (e.g., sputtering or CVD) or by thermal oxidation. The second tunnel layer 30 can be formed on the back side 16. Additionally, the second tunnel layer 30 can also be formed on the front side 14. The second tunnel layer 30 can saturate open bonds on the surface of the semiconductor substrate 12. The second tunnel layer 30 can have a thickness of 5 to 200 angstroms.

Subsequently, the second conductive layer 28 is formed (FIG. 6). The second conductive layer 28 can be formed by deposition. The second conductive layer 28 can be deposited using a directional method, for example PVD. The second conductive layer 28 particularly has a doping (e.g., p-type) opposite to that of the first conductive layer 26 (e.g., n-type). Due to the shadowing (with respect to the first direction 52) of the third regions 22 by the first conductive layers 26, the second conductive layer 28 is not formed (or only minimally, in the case of a non-ideally directional deposition) in the third regions 22. Therefore, the third regions 22 particularly contain none or only a minimal amount of the second conductive layer 28. In particular, due to the directional deposition (parallel and opposite to the first direction 52), no or very little of the second conductive layer 28 is deposited in the third regions 22, as these are shadowed by the first conductive layer 26.

However, the second conductive layer 28 can partially deposit in the third regions 22, since PVD (or similar processes) is not exclusively directional. However, since the thickness of the second conductive layer 28 that may be deposited in the third regions 22 is significantly lower than that in the first and second regions 18, 20 and/or the second conductive layer 28 does not fully cover the third regions 22, the second conductive layer 28 in the third regions 22 has such a high resistance (similar to that of insulators) that the efficiency of the solar cell 10 is not negatively affected. If necessary, the second conductive layer 28 can also be removed from the third regions 22, or at least reduced to such an extent that the efficiency of the solar cell 10 is not negatively affected.

Within the first regions 18, the second conductive layer 28 is deposited onto the first conductive layer 26. The layer thickness of the second conductive layer 28 can range from 10 nm to 400 nm. The second conductive layer 28 can have a dopant concentration between 1×10¹⁹ cm⁻³ and 1×10²² cm⁻³. In particular, due to directional deposition, the second conductive layer 28 does not deposit on the front side 14. A high-temperature step may follow to crystallize the first and/or second conductive layers 26, 28, as well as to activate the dopants in the first and/or second conductive layers 26, 28.

The following procedural steps are not explicitly shown, but are explained below with reference to FIGS. 1 to 3:

A dielectric layer 44, 44′ can be deposited to passivate the surface of the front side 14 and the back side 16 (see FIG. 1). The dielectric layer 44, 44′ may comprise or consist essentially of one or more layers, for example of an aluminum oxide, a silicon oxide, and/or silicon nitride, as described herein.

The dielectric layer 44 on the front side 14 and the dielectric layer 44′ on the back side 16 can be identical or different, in particular having different properties. A wet-chemical cleaning step may precede the deposition process of the dielectric layers 44 and 44′. Hydrogen in the dielectric layers 44, 44′ can saturate dangling bonds on the surfaces of the semiconductor substrate 12, particularly in the first and second regions 18, 20, where the first and second conductive layers 26, 28 are. The dielectric layers 44, 44′ can also particularly serve as an anti-reflective coating on the front side 14 and increase the light yield of the solar cell 10.

Subsequently, the first and second electrodes 32, 34 can be formed and/or applied (see FIG. 1) on the back side 16. The first electrodes 32 each contact a second conductive layer 28 in a first region 18. It is also conceivable that the first electrodes 32 pass through the second conductive layer 28 and contact the first conductive layer 26 in the first regions 18. The second electrodes 34 each contact the second conductive layer 28 in a corresponding second region 20.

For the electrodes 32, 34 to contact the underlying second conductive layer 28, the dielectric layer 44′ can have first and second interruptions 46, 48 at corresponding locations. The creation of the interruptions 46, 48 can be carried out, for example, by local ablation, such as laser ablation. Pastes can also be used in the fabrication of the electrodes 32, 34. The first and/or second interruptions 46, 48 can also be produced during a firing (e.g., heating, optionally with accompanying irradiation or an applied voltage) of the pastes if the pastes locally dissolve the dielectric layer 44. The firing step can also have a positive effect on the passivation of the non-metalized surfaces, as hydrogen in the dielectric layer 44′ may be mobilized during the high-temperature step, diffuse to the surfaces of the semiconductor substrate 12, and saturate open bonds there.

The first and/or second interruptions 46, 48 can be implemented continuously as lines or as interrupted patterns in the form of round dots, squares, or segmented lines. The pastes can, for example, contain silver, copper, or aluminum as a conductive metal. After firing, the particles in the pastes sinter together to form the first and second electrodes 32, 34. The first and second electrodes 32, 34 can also include a layer stack (paste stack), for example comprising or made of silver and copper. When using aluminum, the composition of the pastes can be selected in such a way that the aluminum alloys with silicon minimally or not at all. Such a composition is suitable for both polarities (e.g., of conductive layers 26, 28).

It is conceivable that after forming the first conductive layer 26, a first intermediate layer 38 is formed (see FIG. 2). The first intermediate layer 38 can be deposited using a CVD or PVD process. The first intermediate layer 38 can, similar to the first conductive layer 26, be deposited with interruptions in the etching areas 50 (e.g., using a mask), or be removed from the etching areas 50 after forming it on the first conductive layer 26. The first intermediate layer 38 may, for example, have an increased carbon content (e.g., silicon carbide or silicon-rich silicon carbide) or comprise or be made of a silicon oxide (e.g., silicon dioxide). The first intermediate layer 38 can improve or provide a diffusion barrier against dopants or contaminants in otherwise adjacent layers, and can also increase etch stability.

It is also conceivable that, after forming the first tunnel layer 24 and before forming the first conductive layer 26, the second intermediate layer 40 can be formed (see FIG. 3). The second intermediate layer 40 can, for example, include an initially intrinsic or doped silicon layer, as described herein. The second intermediate layer 40 can be removed in the etch regions 50 (e.g., by etching) before etching the etch regions 50. The second intermediate layer 40 can be (further) doped during a high-temperature step by diffusion of dopants from the first conductive layer 26. The second intermediate layer 40 can prevent a reaction between the carbon of the first conductive layer 26 and the oxygen in the first tunnel layer 24.

The foregoing descriptions of specific embodiments of the present invention have been presented for purposes of illustration and description. They are not intended to be exhaustive or to limit the invention to the precise forms disclosed, and obviously many modifications and variations are possible in light of the above teaching. The embodiments were chosen and described in order to best explain the principles of the invention and its practical application, to thereby enable others skilled in the art to best utilize the invention and various embodiments with various modifications as are suited to the particular use contemplated. It is intended that the scope of the invention be defined by the Claims appended hereto and their equivalents.

What is claimed is:

1. A back-contact solar cell, comprising a semiconductor substrate with a front side and a rear side, wherein the rear side includes a plurality of first regions, a plurality of second regions, and a plurality of third regions, the first regions include a first layer stack comprising a first tunnel layer, a first conductive layer, and a second conductive layer, the first conductive layer is etch-resistant or has a lower etch rate than the semiconductor substrate, the second conductive layer comprising amorphous, microcrystalline, or polycrystalline silicon, the second regions include a second layer stack comprising a second tunnel layer and the second conductive layer, the third regions comprise under-etched areas of the first regions, the solar cell comprises a plurality of first electrodes and a plurality of second electrodes, the first electrodes are in the plurality of first regions and contact the second conductive layer, the second electrodes are in the plurality of second regions and contact the second conductive layer, and the first regions are each on a pedestal-like elevation.

2. The back-contact solar cell according to claim 1, wherein the first conductive layers each comprise silicon carbide.

3. The back-contact solar cell according to claim 1, wherein the first conductive layers each comprise carbon-doped silicon.

4. The back-contact solar cell according to claim 1, wherein the first layer stack further comprises a first intermediate layer between the first conductive layer and the second conductive layer.

5. The back-contact solar cell according to claim 4, wherein the first intermediate layer comprises a silicon oxide or a silicon carbide, the silicon carbide having a higher carbon content than the first conductive layer.

6. The back-contact solar cell according to claim 1, wherein the first layer stack further comprises a second intermediate layer between the first conductive layer and the first tunnel layer.

7. The back-contact solar cell according to claim 6, wherein the second intermediate layer comprises doped polycrystalline silicon.

8. The back-contact solar cell according to claim 1, wherein each of the third regions are undoped.

9. The back-contact solar cell according to claim 1, wherein each of the third regions have a third conductive layer.

10. The back-contact solar cell according to claim 1, further comprising a fourth conductive layer on the front side.

11. The back-contact solar cell according to claim 1, wherein each of the first conductive layers, the second conductive layers, the first intermediate layers, the second intermediate layers, and optionally the first tunnel layers and the second tunnel layers are without any perforations or openings.

12. The back-contact solar cell according to claim 1, further comprising a first dielectric layer or stack of dielectric layers on the front side as an outermost layer.

13. The back-contact solar cell according to claim 1, further comprising a second dielectric layer or stack of dielectric layers on the rear side as an outermost layer, wherein the second dielectric layer or stack of dielectric layers comprises a first interruption in each of the first regions and a second interruption in each of the second regions, the first electrodes contact the second conductive layer through the first interruptions, and the second electrodes contact the second conductive layer through the second interruptions.

14. The back-contact solar cell according to claim 13, wherein each of the third regions comprise the second tunnel layer or the second dielectric layer or stack of dielectric layers.

15. The back-contact solar cell according to claim 1, wherein each of the first regions and the second regions comprise a passivating contact.

16. A method of producing a back-contact solar cell, comprising:
providing a semiconductor substrate with a front side and a rear side;
forming a first tunnel layer on the rear side of the semiconductor substrate;
forming a first conductive layer on the first tunnel layer, wherein the first conductive layer is etch-resistant or has a lower etch rate than the semiconductor substrate, and the first conductive layer has interruptions in a plurality of etch areas or is removed in the plurality of etch areas;
etching the first tunnel layer and the semiconductor substrate in the etch areas to at least partially undercut the first conductive layer, thereby producing pedestal-like elevations and third regions;
forming a second tunnel layer between the pedestal-like elevations; and
forming a second conductive layer in the etch areas by directional deposition, whereby no second conductive layer forms in the third regions due to the shading of the first conductive layer.

17. The method according to claim 16, further comprising:
forming a third conductive layer in the third regions and/or a fourth conductive layer on the front side by furnace diffusion; and
forming a dielectric layer or a dielectric layer stack on the front side and/or the back side as an outermost layer.

18. The method according to claim 16, further comprising:
forming first electrodes and/or second electrodes on the back side, contacting the second conductive layer.

19. The method according to claim 16, further comprising:
forming a first intermediate layer on the first conductive layer.

20. The method according to claim 16, further comprising:
forming a second intermediate layer on the first tunnel layer, before forming the first conductive layer, and removing the second intermediate layer in the etch areas before etching the first tunnel layer and the semiconductor substrate in the etching areas.
